(19) United States
(12) Patent Application Publication
(10) Pub. No.: US 2004/0083976 A1
(43) Pub. Date: May 6, 2004

(54) Modified deposition ring to eliminate backside and wafer edge coating

(75) Inventor: Narayanan Meyyappan, Penang (MY)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: SilTerra Malaysia Sdn. Bhd., Kulim (MY)

(21) Appl. No.: 10/255,545

(22) Filed: Sep. 25, 2002

(51) Int. Cl. H05H 1/24; C23C 16/00

(52) U.S. Cl. 118/728; 427/569

(57) ABSTRACT

The present invention relates to a method and a device for reducing or eliminating coating on a backside and an outer edge of a substrate which is supported on a substrate support during plasma substrate processing, the substrate support supporting a central portion of the backside of the substrate. The device comprises a deposition ring configured to circumscribe the substrate support to abut an outer edge of the substrate support with an inner edge of the deposition ring. The deposition ring has an inner shielding region configured to abut a peripheral portion of the backside of the substrate which extends beyond the outer edge of the substrate support. The deposition ring has an edge shielding region configured to circumscribe the outer edge of the substrate without abutting the outer edge of the substrate. The edge shielding region is configured to be spaced from the outer edge of the substrate by an edge shielding space which is equal to or smaller than an anode dark space, which is sufficiently small to prevent plasma from forming in the edge shielding space so as to prevent coating on the outer edge of the substrate during plasma substrate processing.

### BACKGROUND OF THE INVENTION

The present invention relates generally to semiconductor manufacturing and, more particularly, to eliminating backside and edge coating of a substrate during processing of the substrate.

In the fabrication of integrated circuits, equipment has been developed to automate substrate processing by performing several sequences of processing steps without removing the substrate from a vacuum environment, thereby reducing transfer times and contamination of substrates. A robot in a central transfer chamber passes substrates through slit valves in the various connected processing chambers and retrieves them after processing in the chambers is complete.

The processing steps carried out in the vacuum chambers typically involve the deposition or etching of multiple metal, dielectric, and semiconductor film layers on the surface of a substrate. Examples of such processes include chemical vapor deposition (CVD), physical vapor deposition (PVD), and etching processes. Although the present invention pertains primarily to PVD processes, it may have application in other processes as well.

Physical vapor deposition is a semiconductor deposition technique using physical methods often employed to deposit a metal layer on a semiconductor wafer. Advanced interconnect systems currently require extensive use of liners, glue layers and barrier layers. Titanium (Ti) and titanium nitride (TiN) thin films are used for providing such layers to facilitate the integration of tungsten (W) and aluminum (Al) filled plugs for contacts and vias. In some CMOS processes, Ti and TiN films are deposited by PVD using magnetron sputtering. PVD processing of Ti, TiN, and Al is conventionally known as the metal slab.

Currently, a PVD system employs a shadow ring to reduce wafer edge deposition. The shadow ring exposes the wafer edge and about 3 mm of the wafer backside along the periphery, allowing some deposition in the wafer edge and peripheral portion of the backside. The space between the shadow ring and the wafer edge is typically about 4.57 mm. During the deposition of 1000 nm of Al on the front side of the wafer, the wafer edge typically receives Al deposition of about 350 nm and the backside typically receives some Al deposition of decreasing thickness from the wafer edge to zero deposition at about 3 mm from the edge.

FIG. 1 shows a conventional deposition ring 10 which is disposed around a substrate support 12 such as an e-clamp for supporting a substrate or wafer 14. The inner edge 18 of the deposition ring 10 abuts the outer edge of the substrate support 12. The deposition ring 10 includes pins or bumps 20 which serve as a centering mechanism for the substrate 14 and prevent the substrate 14 from sliding off during the e-clamp release by Argon pressure. The deposition ring 10 leaves the edge 22 and the peripheral portion 24 of the backside of the substrate 14 exposed, and allows some deposition in those areas, as illustrated in the layer 26 (e.g., Al) deposited on the substrate 14.

The wafer edge and backside deposition does not contribute to the functionality of the circuit. Instead, it can cause particle contamination in the chamber. After several layers are deposited (e.g., 4-5 layers), they tend to delaminate, peel, and eventually flake off as particles. The particles are a source of contamination that can reduce the chip yield. One temporary solution is to add a cleaning step via a backside wafer scrubber that removes the flakes. This extra step adds cost to the manufacturing process, takes up more cycle time, and does not remove all the flakes since the wafer is held around the edge covering up to about 1 mm of the edge.

### BRIEF SUMMARY OF THE INVENTION

The present invention relates to a method and an apparatus for eliminating wafer backside and wafer edge coating during wafer processing such as PVD process of Ti, TiN, and Al. In specific embodiments, a modified deposition ring is provided to abut the backside of the substrate to prevent backside coating. The modified deposition ring further includes an edge shielding region configured to circumscribe the outer edge of the substrate and to be spaced therefrom by an edge shielding space which is equal to or smaller than an anode dark space. Such a space is sufficiently small to prevent plasma from forming in the edge shielding space so as to prevent coating on the outer edge of the substrate during plasma substrate processing.

An aspect of the present invention is directed to a device for reducing or eliminating coating on a backside and an outer edge of a substrate which is supported on a substrate support during plasma substrate processing, the substrate support supporting a central portion of the backside of the substrate. The device comprises a deposition ring configured to circumscribe the substrate support to abut an outer edge of the substrate support with an inner edge of the deposition ring. The deposition ring has an inner shielding region configured to abut a peripheral portion of the backside of the substrate which extends beyond the outer edge of the substrate support. The deposition ring has an edge shielding region configured to circumscribe the outer edge of the substrate without abutting the outer edge of the substrate. The edge shielding region is configured to be spaced from the outer edge of the substrate by an edge shielding space which is equal to or smaller than an anode dark space, which is sufficiently small to prevent plasma from forming in the edge shielding space so as to prevent coating on the outer edge of the substrate during plasma substrate processing.

In some embodiments, the anode dark space is at most about 3 mm., The edge shielding space is about 2.3 mm. The edge shielding space may be at least about 1 mm to provide sufficient clearance for loading the substrate with a robot. The deposition ring comprises stainless steel.

In accordance with another aspect of the invention, a method is provided for reducing or eliminating coating on a backside and an outer edge of a substrate which is supported on a substrate support during plasma substrate processing, the substrate support supporting a central portion of the backside of the substrate. The method comprises providing a shielding ring having an inner shielding region to abut a peripheral portion of the backside of the substrate which extends beyond the outer edge of the substrate support; and circumscribing the outer edge of the substrate with an edge shielding region without abutting the outer edge of the substrate. The edge shielding region is spaced from the outer edge of the substrate by an edge shielding space which is equal to or smaller than an anode dark space, which is sufficiently small to prevent plasma from forming in the edge shielding space so as to prevent coating on the outer edge of the substrate during plasma substrate processing.

In some embodiments, the method further comprises loading the substrate on the substrate support using a robot with sufficient clearance from the edge shielding region of the shielding ring provided by the edge shielding space. The edge shielding space may be at least about 1 mm. The shielding ring may be a part of a deposition ring which circumscribes the substrate support to abut an outer edge of the substrate support with an inner edge of the deposition ring. The edge shielding region of the shielding ring desirably has sufficient height to prevent the substrate from sliding off the substrate support.

### BRIEF DESCRIPTION OF THE DRAWINGS

FIG. 1 is a simplified elevational view of a conventional deposition ring disposed around a substrate support; and

FIG. 2 is a simplified elevational view of a modified deposition ring according to an embodiment of the present invention.

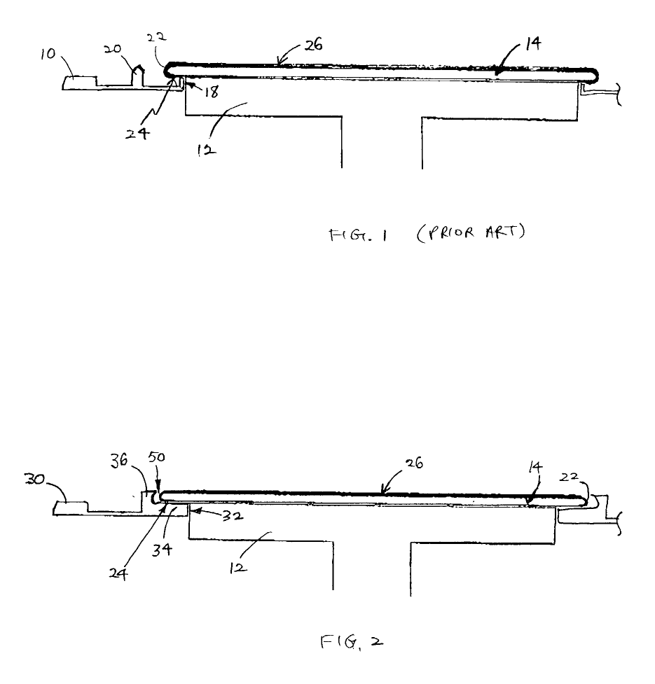

### DETAILED DESCRIPTION OF THE INVENTION

FIG. 2 shows a modified deposition ring 30 according to an embodiment of the invention. The deposition ring 30 circumscribes the substrate support 12, and has an inner edge 32 which abuts the outer edge of the substrate support 12. The substrate support 12 is disposed in a plasma chamber. The substrate support 12 serves as an anode, while the material to be deposited is the cathode.

The deposition ring 30 has an inner shielding region 34 adjacent to the inner edge 32. The inner shielding region 34 is generally coplanar with the upper surface of the substrate support 12 and abuts the peripheral portion 24 of the backside of the substrate 14 which extends beyond the outer edge of the substrate support 12. The inner shielding region 34 shadows the peripheral portion 24 of the backside of the substrate 14 to prevent film deposition thereon. The deposition ring 30 further includes an edge shielding region 36 which circumscribes the outer edge 22 of the substrate without abutting the outer edge 22. The edge shielding region 36 is spaced from the outer edge 22 of the substrate 14 by a shielding space which is referred to as an anode dark space 50. The anode dark space 50 is sufficiently small to prevent plasma from forming in the space 50 so as to prevent deposition or coating on the outer edge 22 of the substrate 14 during plasma substrate processing.

For a plasma having a glow discharge, the glow can be produced by applying a potential difference between two electrodes in a gas. The potential drops rapidly close to the cathode, varies slowly in the plasma, and changes again close to the anode. The electric fields in the system are restricted to sheaths at each of the electrodes. The sheath fields are such as to repel electrons trying to reach either electrode. Electrons originating at the cathode will be accelerated, collide, transfer energy, leave by diffusion and recombination, slow by the anode, and get transferred into the outside circuit. The luminous glow is produced because the electrons have enough energy to generate visible light by excitation collisions. Since there is a continuous loss of electrons, there must be an equal degree of ionization going on to maintain the steady state. The energy is being continuously transferred out of the discharge and hence the energy balance must be satisfied also. Simplistically, the electrons absorb energy from the field, accelerate, and ionize some atoms, and the process becomes continuous. Additional electrons are produced by secondary emission from the cathode. These are very important to maintaining a sustainable discharge. Three basic regions are the cathode region, the glow regions, and the anode region. The anode dark space is the space between the anode glow and the anode itself, and is also referred to as the anode sheath. It has negative space charge due to electrons traveling from the positive column to the anode. There is a higher electric field than the positive column. The positive column is a quasi-neutral, small electric field (typically about 1 V/cm), which is just large enough to maintain the degree of ionization at its cathode end. The positive column is a long, uniform glow, except when standing or moving striations are triggered spontaneously, or ionization waves are triggered by a disturbance. The anode pulls electrons out of the positive column and acts like a Langmuir probe in electron saturation.

The size of the anode dark space is a function of various factors including the type of gas in the plasma, voltages, electrode materials, and pressure. See, e.g., Lieberman & Lichtenberg, “Principles of Plasma Discharges and Materials Processing,” John Wiley & Sons. Anode and Cathode fall voltages depend on the type of gas used for the plasma and the electrode materials. The fall voltages have a strong dependency on the type of gas and has a relatively weak dependency on the electrode materials.

In one example, the gas is argon, the anode material is stainless steel, and the cathode is the material to be deposited (i.e., aluminum). The normal cathode fall voltage is about 100 V for aluminum and about 165 V for stainless steel. The corresponding normal DC glow cathode fall thicknesses are 0.29 Torr-cm and 0.33 Torr-cm, respectively. For a DC Magnetron discharge used today for aluminum sputtering, the fall thicknesses are substantially smaller (typically by about one order of magnitude or more). The operating pressure may typically be about 5 mTorr. For a normal DC glow discharge, the cathode fall thicknesses or cathode dark spaces are 0.29 Torr-cm/5 mTorr=58 cm, and 0.33 Torr-cm/5 mTorr=66 cm, respectively, for aluminum and stainless steel. The voltage drop in the anode region is very small due to the retarding electric field in the neighborhood of the anode. The anode field strength is approximately 1/10 of the cathode field. Given the same operating pressure and anode materials, the anode fall thicknesses or anode dark spaces are approximately 5.8 cm and 6.6 cm for aluminum and stainless steel, respectively, based on the reduced electric field strength. For a normal DC glow discharge, any space less than about 6.6 cm will be an anode dark space and thus will not have material deposition in that space.

For a DC Magnetron discharge, the anode dark space is estimated to be about 3 mm for the same operating conditions, materials, and voltages as in the example. As long as the space between the deposition ring 30 and the outer edge 22 of the substrate 14 is less than about 3 mm, there is no deposition on the wafer edge 22. In one specific example, the space between the deposition ring 30 and the outer edge 22 of the substrate 14 is about 2.3 mm.

The deposition ring 30 is typically made of a metal, such as 316 Stainless Steel. The use of a material such as 316 Stainless Steel makes it possible to recycle the kit by selectively etching off the deposition film (e.g., aluminum film). By preventing deposition or coating of the wafer backside and edge, the use of the modified deposition ring 30 avoids the peeling and flaking of such undesirable deposition or coating and thus increases the device yield.

The above-described arrangements of apparatus and methods are merely illustrative of applications of the principles of this invention and many other embodiments and modifications may be made without departing from the spirit and scope of the invention as defined in the claims. For instance, the present invention may be implemented for different materials, different gases, different operating conditions, and different processes. The scope of the invention should, therefore, be determined not with reference to the above description, but instead should be determined with reference to the appended claims along with their full scope of equivalents.

What is claimed is:

1. A device for reducing or eliminating coating on a backside and an outer edge of a substrate which is supported on a substrate support during plasma substrate processing, the substrate support supporting a central portion of the backside of the substrate, the device comprising:
a deposition ring configured to circumscribe the substrate support to abut an outer edge of the substrate support with an inner edge of the deposition ring, the deposition ring having an inner shielding region configured to abut a peripheral portion of the backside of the substrate which extends beyond the outer edge of the substrate support, the deposition ring having an edge shielding region configured to circumscribe the outer edge of the substrate without abutting the outer edge of the substrate, the edge shielding region configured to be spaced from the outer edge of the substrate by an edge shielding space which is equal to or smaller than an anode dark space, which is sufficiently small to prevent plasma from forming in the edge shielding space so as to prevent coating on the outer edge of the substrate during plasma substrate processing.

2. The device of claim 1 wherein the anode dark space is at most about 3 mm.

3. The device of claim 2 wherein the edge shielding space is about 2.3 mm.

4. The device of claim 1 wherein the edge shielding space is at least about 1 mm.

5. The device of claim 1 wherein the deposition ring comprises stainless steel.

6. A device for reducing or eliminating coating on a backside and an outer edge of a substrate which is supported on a substrate support during plasma substrate processing, the substrate support supporting a central portion of the backside of the substrate, the device comprising:
a deposition ring configured to circumscribe the substrate support to abut an outer edge of the substrate support with an inner edge of the deposition ring, the deposition ring having an inner shielding region configured to abut a peripheral portion of the backside of the substrate which extends beyond the outer edge of the substrate support, the deposition ring having an edge shielding region configured to circumscribe the outer edge of the substrate without abutting the outer edge of the substrate, the edge shielding region configured to be spaced from the outer edge of the substrate by a edge shielding space of at most about 3 mm.

7. The device of claim 6 wherein the edge shielding space is about 2.3 mm.

8. The device of claim 6 wherein the edge shielding space is at least about 1 mm.

9. The device of claim 6 wherein the deposition ring comprises stainless steel.

10. A method of reducing or eliminating coating on a backside and an outer edge of a substrate which is supported on a substrate support during plasma substrate processing, the substrate support supporting a central portion of the backside of the substrate, the method comprising:
providing a shielding ring having an inner shielding region to abut a peripheral portion of the backside of the substrate which extends beyond the outer edge of the substrate support; and
circumscribing the outer edge of the substrate with an edge shielding region without abutting the outer edge of the substrate, the edge shielding region being spaced from the outer edge of the substrate by an edge shielding space which is equal to or smaller than an anode dark space, which is sufficiently small to prevent plasma from forming in the edge shielding space so as to prevent coating on the outer edge of the substrate during plasma substrate processing.

11. The method of claim 10 wherein the anode dark space is at most about 3 mm.

12. The method of claim 11 wherein the edge shielding space is about 2.3 mm.

13. The method of claim 10 further comprising loading the substrate on the substrate support using a robot with sufficient clearance from the edge shielding region of the shielding ring provided by the edge shielding space.

14. The method of claim 13 wherein the edge shielding space is at least about 1 mm.

15. The method of claim 10 wherein the shielding ring is a part of a deposition ring which circumscribes the substrate support to abut an outer edge of the substrate support with an inner edge of the deposition ring.

16. The method of claim 10 wherein the edge shielding region of the shielding ring has sufficient height to prevent the substrate from sliding off the substrate support.

17. The method of claim 10 wherein the shielding ring comprises stainless steel.
